(19) United States
(12) Patent Application Publication
(10) Pub. No.: US 2026/0262464 A1
(43) Pub. Date: Sep. 3, 2026

(54) SUBSTRATE CLEANING DEVICE, SUBSTRATE CLEANING METHOD, AND SEMICONDUCTOR DEVICE MANUFACTURING METHOD

(71) Applicant: MEIDENSHA CORPORATION, Shinagawa-ku, Tokyo (JP)

(72) Inventors: Toshinori MIURA, Shinagawa-ku, Tokyo (JP); Naoki KATO, Shinagawa-ku, Tokyo (JP); Mitsuru KEKURA, Shinagawa-ku, Tokyo (JP)

(21) Appl. No.: 19/165,058

(22) PCT Filed: Mar. 5, 2024
(86) PCT No.: PCT/JP2024/008231

§ 371 Date: May 13, 2026

(30) Foreign Application Priority Data
Mar. 14, 2023 (JP) 2023-039733

(51) Int. Cl. H10P 70/00; B08B 3/04; B08B 3/08; G03F 7/16

(52) U.S. Cl. CPC H10P 70/23; B08B 3/041; B08B 3/08; G03F 7/16; B08B 2203/005

(57) ABSTRACT

A cleaning device (1) of a substrate(S) includes an ozone water generation unit (2) which receives ozone gas at an ozone concentration of 50 vol % or more and at an ozone partial pressure of 30 kPa (abs) or less and a solvent in a gas-liquid mixer (21), and which generates ozone water, an ozone water supply unit (3) which discharges and supplies the ozone water to the substrate (S), and a miscible liquid supply unit (4) which receives a miscible liquid that is miscible with the ozone water, and which discharges and supplies it as a temperature-capable-of-being-raised liquid to the substrate (S). The ozone water and the miscible liquid are discharged simultaneously or alternately, and the ozone water and the miscible liquid are mixed at a discharge-receiving side part (S1).

### TECHNICAL FIELD

The present invention relates to a technique that can contribute to a substrate cleaning device, a substrate cleaning method and a semiconductor device manufacturing method.

### BACKGROUND ART

A substrate (a semiconductor wafer substrate etc.) used in various electrical devices is subjected to various processes (such as a photolithography process, an etching process, a film formation process, an ion implantation process, and a CMP process), and after each process, the substrate is cleaned as appropriate so that unwanted substances such as particles and organic substances do not remain on a surface of the substrate.

For instance, a lithography process, which is one of the manufacturing processes for a semiconductor device, forms fine patterns on a substrate, and may be repeatedly performed multiple times (e.g. several tens of times to several hundreds of times) to create one semiconductor element.

In this lithography process, as a photosensitive material, a resist (photoresist) made of an organic material or the like is generally used. The resist is applied onto the substrate to form a resist layer, and desired patterns are formed on the resist layer. After the resist layer is used (for instance, after an etching process, a film formation process, an ion implantation process, etc.), it is required to clean the substrate and remove the resist layer as desired (for example, completely remove the resist layer).

In general cleaning, as a cleaning chemical, heated sulfuric acid or hydrogen peroxide solution has been used. However, there is a risk that the waste liquid treatment of the chemical after being used will be a significant burden on the environment. Therefore, in recent years, a method using ozone water having a strong oxidizing power has been attempted as an alternative cleaning method with an extremely low environmental load (for example, Patent Documents 1 to 7, and Non-Patent Documents 1 to 3). Ozone water decomposes appropriately and ultimately becomes oxygen and water. Therefore, the environmental load of the waste liquid treatment is extremely low. For this reason, the ozone water is attracting attention.

Ozone water can be obtained, for instance, by dissolving ozone gas in a solvent, and is preferably supplied to an object to be supplied (a substrate) while maintaining a desired ozone concentration. For instance, Patent Document 4 discloses that, by supplying both warm water and pressurized ozone water to a substrate, the ozone concentration of the ozone water is easily maintained until just before both the warm water and the pressurized ozone water are mixed, and this mixing raises temperature of the ozone water, thereby easily exerting a desired oxidizing power.

### CITATION LIST

### Patent Document

Patent Document 1: Japanese Unexamined Patent Application Publication No. 2002-261068
Patent Document 2: Japanese Patent No. 4444557
Patent Document 3: Japanese Unexamined Patent Application Publication No. 2009-297588
Patent Document 4: Japanese Unexamined Patent Application Publication No. 2021-034672
Patent Document 5: Japanese Patent No. 5332052
Patent Document 6: Japanese Patent No. 7186751
Patent Document 7: Japanese Unexamined Patent Application Publication No. 2008-311257

### Non-Patent Document

Non-Patent Document 1: T. Miura et al, “Novel plasmaless photoresist removal method in gas phase at room temperature”, ECS Transactions, Volume 19, Issue 3, pp. 423 (2009 )
Non-Patent Document 2: T. Miura et al, “Production and Detection of OH Species by a Highly Concentrated Ozone Gas for Thin Film Processing”, ACSIN-12&ICSPM21 (2013)
Non-Patent Document 3: Ozone Handbook (Revised Second Version) Japan Ozone Association

### SUMMARY OF THE INVENTION

As described above, in the case of the method in which ozone gas is merely dissolved in a solvent, it is difficult to obtain high-concentration ozone water. For instance, one method is to pressurize ozone gas and to dissolve it in a solvent, but this method is prone to a rapid self-decomposition reaction of ozone, which may make it difficult to maintain practical safety.

Furthermore, if warm water and pressurized ozone water are merely supplied to a substrate as in Patent Document 4, pressure of ozone water decreases (e.g. pressure of ozone water is returned to normal pressure) while rapidly raising temperature, and ozone water is easily degassed (foams). Ozone water degassed in this manner may have a reduced ozone concentration, and may not be able to exert the desired oxidizing power.

The present invention was made in view of the above circumstances. An object of the present invention is therefore to provide a technique that can contribute to making it easier to safely generate high-concentration ozone water, suppressing attenuation of ozone concentration of the generated ozone water, and making it easier to exhibit the desired oxidizing power.

A substrate cleaning device, a substrate cleaning method and a semiconductor device manufacturing method according to the present invention can contribute to solving the above problem. As one aspect of the substrate cleaning device, a substrate cleaning device comprises: an ozone water generation unit configured to receive, in a gas-liquid mixer, ozone gas and a solvent that can dissolve the ozone gas, and generate ozone water; an ozone water supply unit configured to discharge the ozone water; a miscible liquid supply unit configured to discharge a miscible liquid that is miscible with the ozone water; and a support portion structured to support a substrate so that the substrate is located in a direction of discharge of the ozone water by the ozone water supply unit.

The gas-liquid mixer includes: a solvent flow passage through which the solvent flows; and an ozone gas introduction passage which is connected to the solvent flow passage and which introduces the ozone gas into the solvent flow passage. The gas-liquid mixer receives the ozone gas at an ozone concentration of 50 vol % or more and at an ozone partial pressure of 30 kPa (abs) or less.

In a state in which the substrate is located in the direction of the discharge of the ozone water by the ozone water supply unit, the miscible liquid supply unit is configured to be able to discharge the miscible liquid to a discharge-receiving side part, which is a side where the ozone water is discharged, of the substrate at a temperature that is higher than that of the ozone water discharged by the ozone water supply unit. The ozone water Supply unit and the miscible liquid supply unit are configured to discharge the ozone water and the miscible liquid simultaneously or alternately to mix both of the ozone water and the miscible liquid at the discharge-receiving side part.

As one aspect of the substrate cleaning method, a substrate cleaning method comprises: an ozone water generation step of receiving, in a gas-liquid mixer, ozone gas and a solvent that can dissolve the ozone gas, and generating ozone water; an ozone water supply step of discharging the ozone water to a substrate that is supported by a support portion; and a miscible liquid supply step of discharging a miscible liquid that is miscible with the ozone water, to the substrate.

The gas-liquid mixer includes: a solvent flow passage through which the solvent flows; and an ozone gas introduction passage which is connected to the solvent flow passage and which introduces the ozone gas into the solvent flow passage. The gas-liquid mixer receives the ozone gas at an ozone concentration of 50 vol % or more and at an ozone partial pressure of 30 kPa (abs) or less.

In the miscible liquid supply step, in a state in which the substrate is located in a direction of discharge of the ozone water by the ozone water supply Step, the miscible liquid is discharged to a discharge-receiving side part, which is a side where the ozone water is discharged, of the substrate at a temperature that is higher than that of the ozone water discharged by the ozone water supply step. The ozone water supply step and the miscible liquid supply step are performed simultaneously or alternately, and both of the ozone water and the miscible liquid are mixed at the discharge-receiving side part.

As one aspect of the semiconductor device manufacturing method, a semiconductor device manufacturing method comprises a step of manufacturing a semiconductor device by using a substrate cleaned by the above substrate cleaning method.

According to the present invention described above, it is possible to contribute to making it easier to safely generate high-concentration ozone water, suppressing attenuation of ozone concentration of the generated ozone water, and making it easier to exhibit the desired oxidizing power.

### BRIEF DESCRIPTION OF THE DRAWINGS

FIG. 1 is a schematic diagram for describing an example of a configuration of a substrate cleaning device according to embodiments.

FIG. 2 is a schematic diagram for describing regions R1 to R3 formed on a substrate S.

FIG. 3 is a schematic diagram for describing a discharge configuration according to a first embodiment.

FIG. 4 is a schematic diagram for describing regions R1 to R3 formed on a substrate S, by the discharge configuration of the first embodiment.

FIG. 5 is a schematic diagram for describing a discharge configuration according to a second embodiment.

FIG. 6 is a schematic diagram (showing a shower head supply surface H11) for describing an example of a shower head H.

FIG. 7 is a schematic diagram (showing a shower head supply surface H12) for describing another example of the shower head H.

FIG. 8 is a schematic diagram for describing a discharge configuration according to a third embodiment.

### EMBODIMENTS FOR CARRYING OUT THE INVENTION

A substrate cleaning device, a substrate cleaning method and a semiconductor device manufacturing method according to the embodiments of the present invention are completely different from the configuration in which warm water and pressurized ozone water are merely supplied to and clean a substrate as shown in Patent Document 4.

That is, in the present embodiments, the substrate cleaning device is configured to receive, in a gas-liquid mixer, ozone gas and a solvent that can dissolve the ozone gas (hereinafter, this solvent is simply referred to as a solvent), generate ozone water, and discharge (eject) and supply the ozone water to a substrate as an object to be supplied. The gas-liquid mixer receives the ozone gas at an ozone concentration of 50 vol % or more and at an ozone partial pressure of 30 kPa (abs) or less.

The substrate cleaning device is also configured to discharge (eject) and supply a miscible liquid that is miscible with the ozone water (hereinafter, this miscible liquid is simply referred to as a miscible liquid) to a discharge-receiving side part, which is a side where the ozone water is discharged, of the substrate (hereinafter, this discharge-receiving side part is simply referred to as a discharge-receiving side part) at a temperature (hereinafter, simply referred to as a temperature-capable-of-being-raised) that is higher than that of the discharged ozone water. Further, the substrate cleaning device is configured to discharge both of the ozone water and the temperature-capable-of-being-raised miscible liquid (hereinafter, simply referred to as a temperature-capable-of-being-raised liquid) simultaneously (together) or alternately to mix both of the ozone water and the miscible liquid at the discharge-receiving side part.

According to such configurations, since high-concentration ozone gas with the ozone partial pressure being sufficiently reduced is received and the ozone water is generated, it is possible to sufficiently suppress an occurrence of a rapid self-decomposition reaction of ozone gas, and to maintain practical safety. In addition, the ozone gas received as described above is easily dissolved in the solvent in the gas-liquid mixer, and high-concentration ozone water (for instance, 100 ppm or more) can be safely generated.

Furthermore, when the ozone water is discharged and supplied to the substrate (the discharge-receiving side part), there is no need to pressurize the ozone water as in Patent Document 4, thereby suppressing degassing of the ozone water. Therefore, as compared with Patent Document 4, it is possible to sufficiently suppress attenuation of ozone concentration of the ozone water.

Moreover, the ozone water discharged to the discharge-receiving side part of the substrate (the ozone water remaining on the discharge-receiving side part) is mixed with the temperature-capable-of-being-raised liquid, and its temperature is raised, thereby making it easier to exhibit the desired oxidizing power. It is therefore possible to obtain the desired cleaning effect.

The substrate cleaning device, a substrate cleaning method and a semiconductor device manufacturing method according to the embodiments use the ozone water generated by receiving the high-concentration ozone gas with the ozone partial pressure being sufficiently reduced, and are configured so that the ozone water discharged to the substrate is mixed with the temperature-capable-of-being-raised liquid, and its temperature is increased. That is, the design of the configurations according to the embodiments can be modified by appropriately applying common technical knowledge in various fields (for example, the ozone field, cleaning field, semiconductor, etc.), and appropriately referring to prior art documents, etc. as necessary. As examples, the configurations are shown in the following embodiments described below.

In the following embodiments, the same element or component is denoted by the same reference sign, and its explanation will be omitted. Furthermore, in the drawings, white arrows represent a discharge state (or an ejection state) of the ozone water, and black arrows represent a discharge state (or an ejection state) of the temperature-capable-of-being-raised liquid.

### Reference

For instance, in a case of a conventional ozone gas generator (an ozonizer), ozone gas that can be generated by the ozonizer is low in concentration (for example, an ozone concentration of 20 vol % or less), and it may contain a large amount of gas (hereinafter, referred to as non-ozone components) made of components (for example, oxygen, etc.) other than ozone. When using such low-concentration ozone gas, it is difficult to generate high-concentration ozone water, and many non-ozone components will be dissolved.

In addition, the high-concentration ozone water obtained by dissolving the low-concentration ozone gas in a solvent under high pressure contains not only the ozone component but also non-ozone components that are dissolved in a supersaturated state. When such ozone water is released into the atmosphere, the non-ozone components tend to cause degassing (for example, bubbles are generated and scattered into the atmosphere), and the ozone components also tend to scatter, making it impossible to maintain a high concentration of the ozone water.

In recent years, it has become possible to generate highly concentrated ozone gas (e.g., ozone concentration of 50 vol % or more) by concentrating ozone gas generated by an ozonizer or the like using, for example, an adsorption concentration method (a method using surface adsorption by silica gel or the like) or a cooling concentration method.

For instance, Meidensha's cooling concentration type ozone gas generator (product name, Pure Ozone Generator) can generate ozone gas with an extremely high concentration (ozone concentration of 90 vol % or more), which is close to 100 vol %, and has been certified to the international safety standard SEMI-S2, and achieves practical safety.

However, even with the concentrated ozone gas as described above, it is necessary to maintain a reduced pressure state to prevent a rapid self-decomposition reaction. Because of this, it is difficult to apply this method to a configuration in which the ozone gas is received in a gas-liquid mixer under a high pressure state and the ozone water is generated.

On the other hand, in the present embodiments, an ozone water generation unit 2 described below is configured such that ozone gas is received in the gas-liquid mixer in a reduced pressure state (ozone partial pressure of 30 kPa (abs) or less). Therefore, even the concentrated ozone gas with extremely high concentration as described above can be safely used, and it is fully possible to generate the ozone water with the desired high concentration.

As a specific example, when the ozone gas received in the gas-liquid mixer has an ozone concentration of 90 vol % or more and an oxygen concentration of less than 10 vol %, the ozone gas can be safely maintained by reducing the total pressure of the ozone gas to a reduced pressure of 30 kPa (abs) or less (i.e. a state in which the ozone partial pressure is 30 kPa (abs) or less).

In addition, in the case of ozone gas with an ozone concentration of vol % or more and an oxygen concentration of less than 50 vol %, the ozone gas can be safely maintained by reducing the total pressure of the ozone gas to a reduced pressure of 60 kPa (abs) or less (i.e. a state in which the ozone partial pressure is 30 kPa (abs) or less).

### Embodiments

### Main Configuration of Cleaning Device 1 according to Embodiments

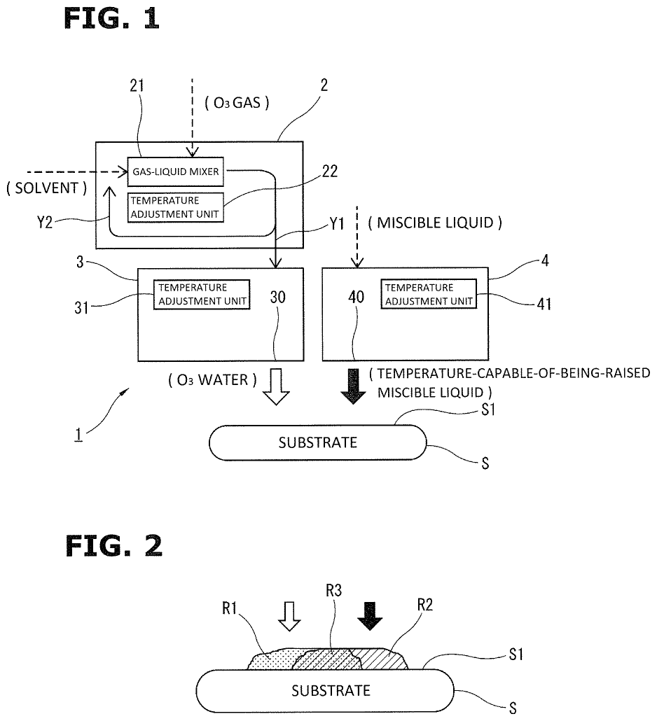

FIG. 1 is a schematic diagram for describing an example of a configuration of a substrate cleaning device 1 according to embodiments. This device 1 includes, as its main elements, an ozone water generation unit 2 that receives ozone gas and a solvent in a gas-liquid mixer 21 and generates ozone water, an ozone water supply unit 3 that discharges (ejects) and supplies the ozone water to a substrate S, and a miscible liquid supply unit 4 that receives a miscible liquid and discharges (ejects) and supplies it as a temperature-capable-of-being-raised liquid onto the substrate S.

This device 1 can be operated by appropriately controlling the ozone water generation unit 2, the ozone water supply unit 3, the miscible liquid supply unit 4, etc., for instance, by a control unit (not shown). An example of the control unit is a configuration that acquires the status of each of the ozone water generation unit 2, the ozone water supply unit 3, the miscible liquid supply unit 4, etc. (e.g. temperature, flow amount (flow rate), pressure, or the like of each of the solvent, the ozone water and the miscible liquid; hereinafter, simply referred to as a device status) as appropriate, and controls the device status, or controls discharge of each of the ozone water and the temperature-capable-of-being-raised liquid (for instance, as described later, performs the control so as to discharge the ozone water and the temperature-capable-of-being-raised liquid simultaneously or alternately).

As flow passages (e.g. flow passages indicated by arrows Y1, Y2) of the solvent and the ozone water in the ozone water generation unit 2, a flow passage (not shown) of the ozone water in the ozone water supply unit 3, and a flow passage (not shown) of the miscible liquid in the miscible liquid supply unit 4, various configurations can be used. As an example of the configurations, it is a configuration in which various pipes etc. are applied. However, both of the flow passage of the ozone water in the ozone water supply unit 3 and the flow passage of the miscible liquid in the miscible liquid supply unit 4 are configured to be independent of each other (that is, both do not communicate with each other).

In addition to the configuration in which the pipes etc. are applied as mentioned above, for instance, as illustrated in FIG. 1, temperature adjustment units (e.g. heaters or coolers) 22, 31, and 41 could be provided in each of the flow passages, and various flow passage components or devices (e.g. open/closure valves, pumps, storage tanks, measurement instruments, etc.) may be provided in each of the flow passages. Here, if impurities (in the case of metal piping, impurities of metal ions etc. generated by dissolution of the inner peripheral surface of the piping) may be mixed in each of the flow passages, it is preferable to configure the flow passages so as to suppress such mixing. For instance, the temperature adjustment units 22, 31, and 41 may be installed on outer peripheral sides of the respective flow passages (e.g. on outer peripheral sides of the respective pipes) so as to be able to indirectly adjust temperature of inner peripheral sides of the respective flow passages. In addition, when the metal piping is used, an inner peripheral surface of the piping may be coated with Teflon (registered trademark) or the like.

The substrate cleaning device 1 is used such that the ozone water generation unit 2 generates the ozone water (an ozone water generation step), and the ozone water supply unit 3 and the miscible liquid supply unit 4 discharge (eject) the ozone water and the temperature-capable-of-being-raised liquid respectively (an ozone water supply step, and a miscible liquid supply step, both described later) simultaneously or alternately, with a discharge-receiving side part S1 of the substrate S being located in a direction of the discharge of the ozone water by the ozone water supply unit 3 and in a direction of the discharge of the temperature-capable-of-being-raised liquid by the miscible liquid supply unit 4.

With this, for instance, as illustrated in FIG. 2, a region R1 where the ozone water is present, a region R2 where the temperature-capable-of-being-raised liquid is present, and a region R3 where the regions R1 and R2 overlap each other are formed on or at the discharge-receiving side part S1 of the substrate S. That is, the ozone water in the region R1 and the temperature-capable-of-being-raised liquid in the region R2 mix with each other in the region R3, then ozone water existing in the region R3 (and in a surrounding area of the region R3) absorbs heat of the temperature-capable-of-being-raised liquid, and temperature of the ozone water increases. An oxidizing power of this temperature-raised ozone water is increased.

The temperature-raised ozone water as described above may generate OH radicals due to ozonolysis. Although these OH radicals have relatively high activity, because their lives are short as compared with ozone, the OH radicals tend to disappear immediately after their generation (the OH radicals tend to react with the surrounding substances and disappear immediately after the generation, because of their low reactivity selectivity). However, as depicted in FIG. 2, OH radicals generated on or at the discharge-receiving side part S1 are more likely to act effectively on the discharge-receiving side part S1 before disappearing.

Therefore, since the ozone water on or at the discharge-receiving side part S1 has a reaction velocity constant that is likely to increase (for instance, by several orders of magnitude) due to the generation of OH radicals, even when the ozone water is diluted with the temperature-capable-of-being-raised liquid, the ozone water has a sufficient oxidizing power.

### Example of Configuration of Ozone Water Generation Unit 2

The ozone water generation unit 2 shown in FIG. 1 is configured such that the gas-liquid mixer 21 receives ozone gas at an ozone concentration of 50 vol % or more and at an ozone partial pressure of 30 kPa (abs) or less while receiving a solvent, and dissolves the ozone gas in the solvent, thereby generating high-concentration ozone water (for instance, 100 ppm or more) . Furthermore, the ozone water generation unit 2 is configured to be able to lead the generated ozone water to the next ozone water supply unit 3 (e.g. through the arrow Y1).

As the gas-liquid mixer 21, for instance, an ejector, an aspirator, a jet pump, etc. could be used, but the gas-liquid mixer 21 is not limited to these components, and various other components may be used. That is, the gas-liquid mixer 21 is not limited as long as it has a solvent flow passage (not shown) through which the received solvent flows, and an ozone gas introduction passage (not shown) which is connected to the solvent flow passage and which introduces the received ozone gas into the solvent flow passage.

According to the gas-liquid mixer 21 configured to have the solvent flow passage and the ozone gas introduction passage as described above, a suction pressure according to Bernoulli's theorem is generated in the ozone gas introduction passage in accordance with a flow amount (a flow velocity) of the solvent flowing in the solvent flow passage. In addition, vapor according to a saturated vapor pressure of the solvent is generated in the ozone gas introduction passage. For instance, when the solvent is raw water, it has the same properties (saturated vapor pressure characteristics and water vapor pressure characteristics) as water.

According to such properties or characteristics of the solvent and a pressure (hereinafter, simply referred to as a receiving pressure) at which the ozone gas is received by the gas-liquid mixer 21, it is possible to derive a solvent temperature range (hereinafter, simply referred to as a suction possible range) in which a vapor pressure in the ozone gas introduction passage of the gas-liquid mixer 21 becomes lower than the receiving pressure. It is preferable that this suction possible range be set as appropriate (for instance, 25° C. or lower, as in par. [0023] of Japanese Patent No. 4296393) in consideration of general dissolution characteristics (or general solubility characteristics) (the tendency of the solubility to improve as the temperature of the solvent decreases) of gas in a solvent. Therefore, when the solvent temperature deviates from the suction possible range, for instance, the solvent temperature is adjusted in advance (e.g. adjusted by a temperature adjustment unit (not shown) ) before the gas-liquid mixer 21 receives the solvent, or the solvent temperature is adjusted by operating the temperature adjustment unit 22.

Before being delivered to the next ozone water supply unit 3, a concentration adjustment gas for stabilizing the ozone concentration may be added to the ozone water generated by the gas-liquid mixer 21, or the ozone water may be circulated (for instance, as indicated by the arrow Y2, the ozone water is circulated so as to be fed back to an upstream side of the gas-liquid mixer 21) or temporarily stored in the ozone water generation unit 2. When increasing the concentration by the concentration adjustment gas, for instance, by adding carbon dioxide (carbonic acid gas) etc. to the ozone water, the ozone water is made acidic.

Any solvent that can dissolve ozone gas can be used as the solvent. As an example of the solvent, it is raw water, pure water, ultrapure water, etc.

Furthermore, if necessary, the purity of the solvent may be increased by using a pure water generation device (not shown) etc.

The ozone gas can be generated by various ozone gas generation devices as long as the gas-liquid mixer 21 receives ozone gas at an ozone concentration of 50 vol % or more and at an ozone partial pressure of 30 kPa (abs) or less. As an example of the ozone gas generation devices, an ozone gas generator (product name, Pure Ozone Generator) manufactured by Meidensha Corporation may be used.

According to such ozone water generation unit 2, it is possible to safely generate ozone water with a high concentration of 100 ppm or more (e.g. 300 to 400 ppm).

### Example of Configuration of Ozone Water Supply Unit 3

The ozone water supply unit 3 shown in FIG. 1 is configured to be able to discharge (eject), from a discharge portion 30, the ozone water introduced from the ozone water generation unit 2. However, as its discharge configuration, various configurations can be used as long as they can discharge (eject) and supply the ozone water to the discharge-receiving side part S1 of the substrate S. An example of the configurations is a configuration in which the ozone water is discharged (ejected) through an ejection nozzle 32 or outlets 33 of a shower head H as shown in embodiments 1 to 3 described later.

Before being discharged to the substrate S, the ozone water in the ozone water supply unit 3 may be temperature-adjusted (e.g. cooled by the temperature adjustment unit 31) in order to maintain the ozone concentration, or temporarily stored in the ozone water supply unit 3.

The temperature of the ozone water when being discharged to the substrate S can be set as appropriate according to the temperature-capable-of-being-raised liquid, as long as it is within a range in which the ozone water does not become a solidification state and in which the temperature of the ozone water can be increased by the temperature-capable-of-being-raised liquid.

### Example of Configuration of Miscible Liquid Supply Unit 4

The miscible liquid supply unit 4 shown in FIG. 1 is configured to be able to receive a miscible liquid and discharge (eject) a temperature-capable-of-being-raised liquid from a discharge portion 40. However, as its discharge configuration, various configurations can be used as long as they can discharge (eject) and supply the temperature-capable-of-being-raised liquid (the miscible liquid) to the discharge-receiving side part S1 of the substrate S. An example of the configurations is a configuration in which the temperature-capable-of-being-raised liquid (the miscible liquid) is discharged (ejected) through an ejection nozzle 42 or outlets 43 of the shower head H as shown in the embodiments 1 to 3 described later.

Before being discharged to the discharge-receiving side part S1 of the substrate S (before reaching the discharge-receiving side part S1), the miscible liquid in the miscible liquid supply unit 4 may be temperature-adjusted (e.g. heated by the temperature adjustment unit 41) to a temperature capable of being raised (a temperature at which the miscible liquid can be heated). However, if the miscible liquid has already reached the temperature-capable-of-being-raised when being received in the miscible liquid supply unit 4, the miscible liquid may be discharged as it is.

Alternatively, the miscible liquid may be temporarily stored in the miscible liquid supply unit 4.

As the miscible liquid, any liquid can be used as long as the liquid is miscible with the ozone water. As an example of the liquid, it is raw water, pure water, ultrapure water, ion-exchange water, basic aqueous solution, acidic aqueous solution, etc. However, although an organic solvent such as lower alcohol is miscible with the ozone water, because C—C bonds of the organic solvent may be broken by ozone. Therefore, if this affects the substrate S in some way, the organic solvent is undesirable. It is also possible to use tap water, but it is preferable to use the tap water after increasing its purity by using a pure water generation device (not shown) etc., as necessary (e.g. depending on the type of the substrate S).

The temperature-capable-of-being-raised of the miscible liquid can be set as appropriate. As an example, if the ozone water is at room temperature (e.g. 5° C. to 35° C.), the temperature-capable-of-being-raised may be set to a temperature (e.g. 40° C. or higher) that is higher than the room temperature. By setting the temperature-capable-of-being-raised in this manner, thermal energy of the miscible liquid (the temperature-capable-of-being-raised liquid) can be given to the ozone water, thereby promoting the generation of OH radicals. In addition, if the miscible liquid is the raw water, the pure water, the ultrapure water or the ion-exchange water, an upper limit of the temperature-capable-of-being-raised may be set to 100° C.

### Example of Substrate S

As the substrate S, various objects can be used as long as they can located in a direction of the discharge of the ozone water by the ozone water supply unit 3 and in a direction of the discharge of the temperature-capable-of-being-raised liquid by the miscible liquid supply unit 4, and also they can obtain a desired effect by exertion of the oxidizing power of the ozone water. Examples are various substrates (e.g. semiconductor substrates, glass substrates) that are subjected to cleaning as in Patent Documents 1 to 7, Non-Patent Documents 1 to 3, JP 2017-173461, and JP2017-123402.

As specific examples, when various substrates that are subjected to cleaning are the substrate S, the substrate S is cleaned in each process (a photolithography process, an etching process, a film formation process, an ion implantation process, a CMP process, etc.) by using the device 1 as necessary. This makes it possible to clean the substrate surface so that no unnecessary substances such as particles or organic matter remain on the substrate surface.

For instance, in a photolithography process, a photoresist is applied to the discharge-receiving side part S1 of the substrate S to form a resist layer (e.g. coating layers S1a and S1b described later) (a resist layer formation process), and then the resist layer is washed (cleaned) by the device 1 (a resist layer removal process), making it possible to remove the resist layer as desired.

Furthermore, a hardened layer may be formed on a surface of the resist layer by implanting impurity ions into the surface of the resist layer. In a case of the resist layer having the hardened layer formed thereon, for instance, Patent Document 5 proposes a method of removing the hardened layer in advance by plasma treatment, and then removing the remaining layer by cleaning. However, this method may lead to an increase in size and complexity of the cleaning device, and an increase in the cleaning cost, etc. In addition, Patent Document 6 proposes a method of forming cracks in the hardened layer in advance by high-temperature steam treatment, and then infiltrating ozone water into the resist layer through the cracks to perform cleaning. However, since the hardened layer itself cannot be dissolved, there is a risk that a removal rate of the resist layer will be extremely low.

On the other hand, with the device 1, the high oxidizing power of ozone water can be exerted on the hardened layer as described above. Therefore, it is possible to sufficiently remove the resist layer including the hardened layer without performing the plasma treatment of Patent Document 5 or the high-temperature steam treatment of Patent Document 6. Here, the device 1 may be used in combination with the plasma treatment of Patent Document 5 or the high-temperature steam treatment of Patent Document 6. In this case, it may be easier to remove the resist layer including the hardened layer.

Ion implantation into the resist layer may be set appropriately depending on the target resist layer. For instance, when forming a P-type layer or an N-type layer on the discharge-receiving side part S1 of the substrate S, ion species such as P, As, B, etc. are used as impurity ions, and the ions are implanted at an arbitrary acceleration voltage (e.g. about several hundred kV) and implantation amount (e.g. 10¹³ to 10¹⁵ atoms/cm²).

Furthermore, if the substrate S is porous, the ozone water and the temperature-capable-of-being-raised liquid discharged from the device 1 are present not only on a surface of the substrate S, but may be present on surfaces of micropores formed inside the substrate S. That is, regions R1 to R3 as shown in FIG. 2 are also formed on the surfaces of the micropores, and a desired effect by the oxidizing power of the ozone water can be obtained.

### Others

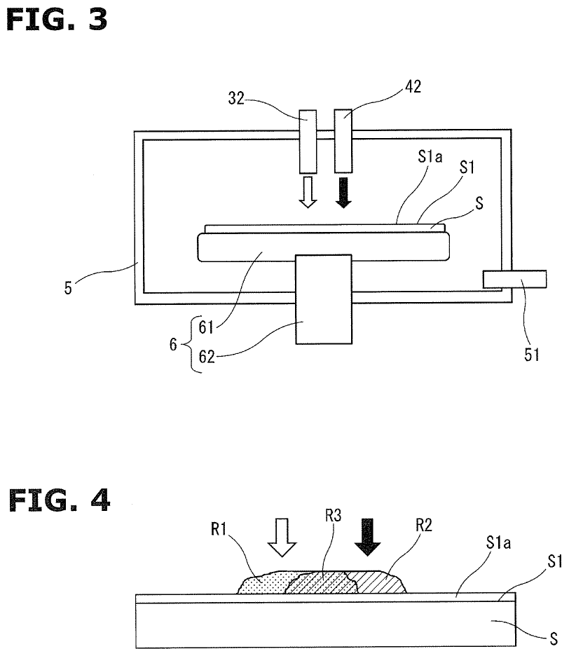

The discharge direction, the discharge flow amount (the discharge flow rate, the discharge flow velocity), the discharge force, etc. of the ozone water discharged by the ozone water supply unit 3 and the temperature-capable-of-being-raised liquid discharged by the miscible liquid supply unit 4 can be appropriately set. For instance, the discharge direction of the ozone water and the temperature-capable-of-being-raised liquid is each set not only simply in a direction orthogonal to the substrate S (in the drawings, vertically upward or downward) as in FIGS. 3, 5 and 8 described later, but may be set in a direction inclined at a predetermined angle with respect to the substrate S.

Furthermore, from the viewpoint of optimizing the mixing efficiency of the ozone water and the temperature-capable-of-being-raised liquid, which is in turn the efficiency of the generation of OH radicals (exerting a high accelerated oxidation effect), it is preferable that an angle of each discharge direction of the ozone water and the temperature-capable-of-being-raised liquid (hereinafter, simply referred to as an ozone water discharge angle, and a temperature-capable-of-being-raised liquid discharge angle) with respect to the substrate S be changed as circumstances demand. For instance, the device 1 may be provided with an angle adjustment function unit that can change each of the ozone water discharge angle and the temperature-capable-of-being-raised liquid discharge angle.

The discharge flow amount and the discharge force of each of the ozone water and the temperature-capable-of-being-raised liquid may be appropriately set according to a positional relationship between the device 1 and the substrate S. It is preferable that the discharge flow amount and the discharge force of the ozone water be set within a range that does not cause degassing etc. of the ozone water after being discharged (ejected).

In addition, when both of the ozone water and the temperature-capable-of-being-raised liquid are discharged, the discharge of the temperature-capable-of-being-raised liquid may be started first, and then the discharge of the ozone water may be started after a predetermined time (for instance, several second to several tens of seconds) has elapsed from the start of the discharge of the temperature-capable-of-being-raised liquid. In this case, for instance, similar to a discharge configuration of the embodiment 1 shown in verification examples 1 and 2 described later, the discharge-receiving side part S1 of the substrate S can be heated in advance (before the discharge of the ozone water is started) by the temperature-capable-of-being-raised liquid, thereby making it easier for OH radicals to be generated, and obtaining an accelerated oxidation effect. This may exert a greater oxidizing power.

Moreover, the substrate S could be supported as appropriate via a support portion 6 as shown in the embodiments 1 to 3 described below, or may be accommodated in a container (a housing, or an enclosure) 5 as appropriate.

### Embodiment 1

FIGS. 3 and 4 are diagrams showing the embodiment 1, and describing an example of the discharge configuration using tubular ejection nozzles 32 and 42. In FIG. 3, the ejection nozzle 32 is provided at a vertically upper side position of a container (such as an atmospheric pressure chamber) 5 that can accommodate therein the substrate S, in a position penetrating the container 5 in inward and outward directions. One end side of this ejection nozzle 32 is connected to the discharge portion 30 of the ozone water supply unit 3 so as to communicate with the discharge portion 30, thereby discharging (ejecting) the ozone water of the ozone water supply unit 3 vertically downward into the container 5.

The ejection nozzle 42 is provided at a position spaced a predetermined distance apart from the ejection nozzle 32, on a vertically upper side of the container 5, in a position penetrating the container 5 in the inward and outward directions. One end side of this ejection nozzle 42 is connected to the discharge portion 40 of the miscible liquid supply unit 4 so as to communicate with the discharge portion 40, thereby discharging (ejecting) the temperature-capable-of-being-raised liquid of the miscible liquid supply unit 4 vertically downward into the container 5.

The substrate S shown in FIGS. 3 and 4 has a flat plate shape. A coating layer S1a such as a resist layer is provided on the discharge-receiving side part S1 that is one end side surface (a surface facing the ejection nozzles 32 and 42) in a thickness direction of the substrate S. The substrate S is rotatably supported by the support portion 6 with the coating layer Sla facing the ejection nozzles 32 and 42.

The support portion 6 of FIG. 3 has a support base 61 that supports the substrate S, and a rotation shaft 62 that extends vertically downward from a center of the support base 61 and rotates the support base 61. As a configuration of the support base 61, it is preferable to support the substrate S without position shift of the substrate S during rotation of the support base 61. As an example, it is a configuration in which the substrate S is supported using a vacuum chuck.

According to the discharge configuration of the present embodiment 1, by performing both of the ozone water discharge step for discharging (ejecting) the ozone water via the ejection nozzle 32, and the miscible liquid discharge step for discharging (ejecting) the temperature-capable-of-being-raised liquid via the ejection nozzle 42 simultaneously or alternately, as depicted in FIG. 4, regions R1 to R3 similar to FIG. 2 are formed on the coating layer S1a of the substrate S. As a result, the oxidizing power of the ozone water can be exerted on the coating layer S1a of the substrate S, and the substrate S can be cleaned by the single wafer cleaning.

Here, while both of the ozone water discharge step and the miscible liquid discharge step are performed simultaneously or alternately as described above, a rotation step for rotating the substrate S, by the support portion 6 could be performed. By appropriately performing this rotation step, the ozone water and the temperature-capable-of-being-raised liquid discharged in the ozone water discharge step and the miscible liquid discharge step respectively easily spread while expanding along a surface of the coating layer S1a by the centrifugal force of the rotation, and the regions R1 to R3 also expand readily. This makes it easier for the oxidizing power of the ozone water to be exerted widely and evenly or uniformly on the coating layer S1a.

Furthermore, when both of the ozone water discharge step and the miscible liquid discharge step are performed alternately, the rotation step may be performed while one of the two steps is stopped and switched to the other step (i.e. while both steps are stopped). In this case, each time the ozone water and the temperature-capable-of-being-raised liquid are discharged, they easily spread while expanding along the surface of the coating layer Sla, and the region R3 may further expand readily. This may make it easier for the oxidizing power of the ozone water to be exerted more widely and evenly or uniformly on the coating layer Sla.

When continuing to rotate the substrate S by the support portion 6 in a state in which both discharge of the ozone water and discharge of the temperature-capable-of-being-raised liquid are stopped, remaining ozone water and remaining temperature-capable-of-being-raised liquid on the coating layer Sla are removed by the centrifugal force of the rotation, and drained, for instance, via a drain portion 51 provided at the container 5.

As a specific example, when both of the ozone water discharge step and the miscible liquid discharge step are performed alternately, a cycle of the ozone water discharge step, the miscible liquid discharge step and the rotation step that is performed in the state in which both of the ozone water discharge step and the miscible liquid discharge step are stopped, is repeated. By repeating such a cycle, it may become easier to efficiently and evenly or uniformly exert the oxidizing power of the ozone water.

The ozone water drained from the drain portion 51 decomposes over time. Therefore, even if the ozone water is released into the natural environment, the burden on the natural environment can be sufficiently suppressed (sufficiently suppressed as compared with a case where, for instance, sulfuric acid, chemical solutions, etc. are used).

### Embodiment 2

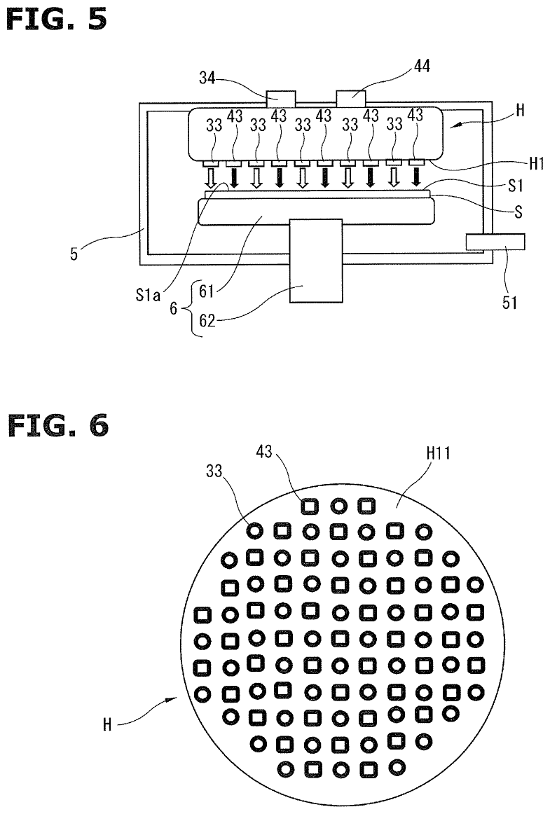

FIGS. 5 to 7 are diagrams showing the embodiment 2, and describing an example of the discharge configuration using a shower head H. In FIG. 5, the shower head H is provided at a vertically upper side position of a container (a housing, or an enclosure) 5. This shower head H is provided, on its shower head supply surface H1 facing the substrate S, with a plurality of ozone water outlets 33 and a plurality of miscible liquid outlets 43.

The shower head H is also provided, at outer side positions of the container 5, with connection parts (such as joints) 34 and 44 that can be connected to the discharge portions 30 and 40 respectively so as to communicate with the discharge portions 30 and 40. The connection part 34 communicates with the ozone water outlets 33 via ozone water flow passages (not shown) provided inside the shower head H, and the connection part 44 communicates with the miscible liquid outlets 43 via temperature-capable-of-being-raised liquid flow passages (not shown) provided inside the shower head H. However, both of the ozone water flow passages and the temperature-capable-of-being-raised liquid flow passages are configured to be independent of each other (that is, both do not communicate with each other). With these configurations, the ozone water and the temperature-capable-of-being-raised liquid can be discharged (ejected) via the outlets 33 and 43.

Shapes etc. of the shower head supply surface H1 and the outlets 33 and 43 are not limited, and can be appropriately set.

For instance, the shower head supply surface H1 may be formed into a shape that is larger than a surface (hereinafter, simply referred to as a discharge-receiving side part facing surface), facing the shower head supply surface H1, of the coating layer S1a, which makes it easier to discharge (eject) the ozone water and the temperature-capable-of-being-raised liquid over the entire area of the discharge-receiving side part facing surface.

As a specific example, when the discharge-receiving side part facing surface is circular in shape, a shower head supply surface H11 is formed into a circular shape as shown in FIG. 6, and the plurality of ozone water outlets 33 and the plurality of miscible liquid outlets 43 may be provided at dispersed positions on the shower head supply surface H11. When the outlets 33 and 43 are provided at the dispersed positions, various arrangements are possible. In the case of FIG. 6, the plurality of outlets 33 are provided so as to be dispersed on the shower head supply surface H11, and the outlets 43 are provided at four sides of each outlet 33.

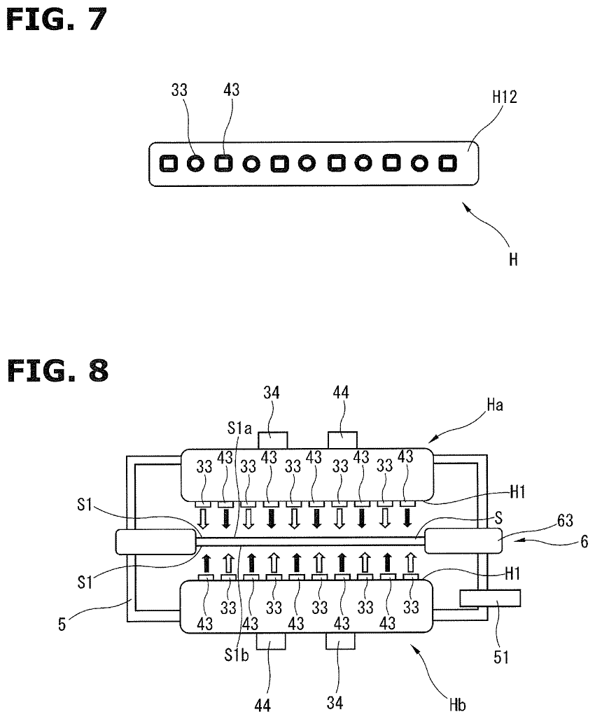

Here, for instance, as shown in FIG. 7, even if a shower head supply surface H12 has an extending band-like shape, when the plurality of outlets 33 and 43 are provided so as to be alternately positioned at predetermined intervals in an extending direction (linearly along the shower head supply surface H12), by appropriately performing the ozone water discharge step, the miscible liquid discharge step and the rotation step in the same manner as the embodiment 1, it is quite possible to discharge (eject) the ozone water and the temperature-capable-of-being-raised liquid over the entire area of the discharge-receiving side part facing surface.

Shapes of the outlets 33 and 43 can be set as appropriate. As examples, they are a circular shape, a rectangular shape, an elliptical shape, a slit shape, etc. It is noted that, for convenience, the outlets 33 and 43 shown in FIGS. 6 and 7 are depicted as having different shapes (the outlet 33 is depicted as a circle, whereas the outlet 43 is depicted as a rectangle), but the outlets 33 and 43 may have the same shape.

According to the present embodiment 2, in addition to the same working and effects as those of the embodiment 1, the following can be said. That is, it is possible to easily discharge (eject) and distribute (spread) the ozone water and the temperature-capable-of-being-raised liquid over the entire area of the discharge-receiving side part facing surface. This may make it easier for the region R3 to be formed over the entire area of the discharge-receiving side part facing surface, and it may become easier to evenly or uniformly and greatly exert the oxidizing power of the ozone water.

### Embodiment 3

FIG. 8 is a diagram showing the embodiment 3, and describing an example of the discharge configuration using a pair of shower heads Ha and Hb. Each of the shower heads Ha and Hb has the same configuration as that of the shower head H of the embodiment 2. The shower heads Ha and Hb are provided at vertically upper and lower sides of a container (a housing, or an enclosure) 5 so as to face each other with respect to the substrate S.

The substrate S of FIG. 8 is provided, on one and other end side surfaces in a thickness direction thereof, with coating layers S1a and S1b, each of which corresponds to the discharge-receiving side part S1. In addition, a support portion 6 supporting the substrate S has a holding portion 63 that holds an outer peripheral edge portion of the substrate S. The support portion 6 is configured to be able to rotatably support the substrate S with the coating layers S1a and S1b facing the shower heads Ha and Hb respectively.

As a specific example of the holding portion 63, it is a configuration in which the outer peripheral edge portion of the substrate S is gripped in the thickness direction, or a configuration (for instance, a configuration in which the outer peripheral edge portion of the substrate S is held using a so-called edge grip) in which the outer peripheral edge portion of the substrate S is held while being pressed inward in a radial direction by a plurality of claw portions arranged radially outside the substrate S.

According to the present embodiment 3, in addition to the same working and effects as those of the embodiments 1 and 2, the following can be said. That is, it is possible to appropriately discharge (eject) the ozone water and the temperature-capable-of-being-raised liquid (simultaneously or alternately) on each discharge-receiving side part S1 on the one end side surface and the other end side surface of the substrate S at the same time. This leads to an improvement in working efficiency (a shortening of work time etc.).

Furthermore, the support portion 6 having the holding portion 63 can appropriately hold and support the substrate S so as to avoid contact with one end side surface and the other end side surface in the thickness direction of the substrate S. This allows the substrate S to be sufficiently cleaned by the single wafer cleaning while being supported so that the one end side surface and the other end side surface of the substrate S are not contaminated.

### Verification Example 1

In a verification 1, the device 1 was applied based on the discharge configuration of the embodiment 1 (hereinafter, simply referred to as an embodiment 1 discharge configuration), and the oxidizing power of ozone water on the substrate S was verified. As a verification condition, a 20 mm×20 mm square chip obtained by cutting a commercially available semiconductor wafer was used as the substrate S. In addition, a 2 μm thick coating layer S1a made of novolac resin-based photoresist was formed (post-baked) on one end, in the thickness direction, of the square chip, and then the chip was supported (not rotated) on the support base 61 of the support portion 6. Furthermore, the ozone water generation unit 2 received ozone gas (ozone concentration 90 vol %, ozone partial pressure 10 kPa (abs) ) generated by an ozone gas generator (product name, Pure Ozone Generator) manufactured by Meidensha Corporation, and generated ozone water with an ozone concentration of approximately 300 ppm, without adding any concentration adjustment gas.

The ejection nozzle 32 was set so that an ejection direction of the ozone water is positioned at the middle of the coating layer S1a, and an ejection angle of the ozone water is approximately 90°. The ejection nozzle 42 was set so that an ejection direction of a temperature-capable-of-being-raised liquid is positioned on one side of a diagonal direction of the coating layer S1a (so that ejected temperature-capable-of-being-raised liquid flows from the one side of the diagonal direction of the coating layer S1a to the other side), and so that an ejection angle of the temperature-capable-of-being-raised liquid is approximately 10°.

Then, first, the temperature-capable-of-being-raised liquid at 80° C. was ejected from the ejection nozzle 42 at a flow rate of 300 cc/min onto the coating layer Sla of the square chip, and 30 seconds later, the ozone water at 4° C. was ejected from the ejection nozzle 32 at a flow rate of 300 cc/min, and a surface condition of the coating layer Sla was observed. As a result, it was observed that within one minute (e.g., several tens of seconds) after the start of ozone water ejection, a middle portion of the coating layer S1a (e.g., the region R3 and its vicinity as shown in FIG. 4) began to peel off and be removed, and the removal rate was 3.5 μm/min.

On the other hand, as a discharge configuration of a comparative example (hereinafter, simply referred to as a comparative example discharge configuration), the ozone water at 80° C. was merely ejected from the ejection nozzle 32 at a flow rate of 300 cc/min onto the coating layer S1a of the square chip, and a surface condition of the coating layer S1a was observed. As a result, it was observed that a middle portion of the coating layer S1a began to peel off and be removed after a few minutes had elapsed from the start of ozone water ejection, and the removal rate was 0.7 μm/min.

Therefore, from the observation results of the embodiment 1 discharge configuration and the comparative example discharge configuration, the following can be said. First, it can be read that the ozone water in the comparative example discharge configuration is at a high temperature (80° C.) before being ejected, and the ozone concentration has already decreased (for example, halved) at the time of ejection, which results in a slower removal rate.

On the other hand, the ozone water in the embodiment 1 discharge configuration is mixed with the temperature-capable-of-being-raised liquid and diluted on or at the middle of the coating layer S1a, and thus the ozone concentration is decreased as in the ozone water in the comparative example discharge configuration. From the viewpoint of the ozone water concentration, it can be expected that the removal rate will be similar to that of the ozone water in the comparative example discharge configuration. £ However, the actual observation result showed that the removal rate was good. This indicates that in the case of the ozone water in the embodiment 1 discharge configuration, the ozone water absorbs heat of the temperature-capable-of-being-raised liquid on or at the coating layer S1a, and the temperature of the ozone water rises (e.g. to about 50° C.), then a reaction velocity constant increases due to the generation of OH radicals. That is, it was confirmed that the ozone water in the embodiment 1 discharge configuration can obtain an accelerated oxidation effect by a sufficient amount of OH radicals on or at the coating layer S1a, thereby exerting a higher oxidizing power.

### Verification Example 2

In a verification 2, first, a photoresist for KrF laser was applied to one end side, in the thickness direction, of the square chip used in the verification example 1 to form a coating layer S1a with a thickness of 0.5 μm, and then an ion species (phosphorus) was ion-implanted into the surface of the coating layer S1a (acceleration voltage 150 kV, injection amount 5×10¹⁴ particles/cm²), thereby forming a hardened layer (or a cured layer) on the surface side of the coating layer S1a.

Then, under the same verification conditions as in the verification example 1, first, the temperature-capable-of-being-raised liquid at 80° C. was ejected from the ejection nozzle 42 at a flow rate of 300 cc/min onto the coating layer S1a (the hardened layer side) of the square chip, and 30 seconds later, the ozone water at 4° C. was ejected from the ejection nozzle 32 at a flow rate of 300 cc/min, and a surface condition of the coating layer S1a was observed. As a result, similar to the verification example 1, it was observed that within one minute (e.g., several tens of seconds) after the start of ozone water ejection, a middle portion of the coating layer Sla (e.g., the region R3 and its vicinity as shown in FIG. 4) began to peel off and be removed, and the removal rate was 0.5 μm/min.

Likewise, using the comparative example discharge configuration, the ozone water at 80° C. was merely ejected from the ejection nozzle 32 at a flow rate of 300 cc/min onto the coating layer S1a of the square chip, and a surface condition of the coating layer S1a was observed. As a result, however, no peeling of the coating layer S1a occurred even after several minutes (10 minutes) elapsed from the start of ozone water ejection.

Therefore, it was confirmed that even though the hardened layer is formed on the surface of the coating layer S1a, the ozone water in the embodiment 1 discharge configuration can obtain an accelerated oxidation effect by a sufficient amount of OH radicals on or at the coating layer S1a, thereby exerting a high oxidizing power.

Although the present invention has been described in detail with respect to the specific examples described above, it will be apparent to those skilled in the art that various modifications are possible within the scope of the technical concept of the present invention, and it is natural that such modifications fall within the scope of the claims.

For instance, in the case of the substrate S shown in FIGS. 3, 5 and 8, the substrate S is supported in a position extending horizontally in the container 5. However, the supporting configuration is not limited to this, but the substrate S could be supported in various positions. For instance, the substrate S may be supported in a position extending vertically in the container 5. In this case, the design of the device 1 may be appropriately modified so that the ejection directions (discharge directions) of the ejection nozzles 32, 42 and the shower heads H, Ha and Hb are each horizontal (i.e. so that the discharge-receiving side part S1 is positioned in each ejection direction of the ozone water and the temperature-capable-of-being-raised liquid).

1.-18. (canceled)

19. A substrate cleaning device comprising:
an ozone water generation unit configured to receive, in a gas-liquid mixer, ozone gas and a solvent that can dissolve the ozone gas, and generate ozone water;
an ozone water supply unit configured to discharge the ozone water;
a miscible liquid supply unit configured to discharge a miscible liquid that is miscible with the ozone water; and
a support portion structured to support a substrate so that the substrate is located in a direction of discharge of the ozone water by the ozone water supply unit,
wherein the gas-liquid mixer includes:
a solvent flow passage through which the solvent flows; and
an ozone gas introduction passage which is connected to the solvent flow passage and which introduces the ozone gas into the solvent flow passage, and the gas-liquid mixer receives the ozone gas at an ozone concentration of 50 vol % or more and at an ozone partial pressure of 30 kPa (abs) or less,
wherein in a state in which the substrate is located in the direction of the discharge of the ozone water by the ozone water supply unit, the miscible liquid supply unit is configured to be able to discharge the miscible liquid to a discharge-receiving side part, which is a side where the ozone water is discharged, of the substrate at a temperature that is higher than that of the ozone water discharged by the ozone water supply unit, and
wherein the ozone water supply unit and the miscible liquid supply unit are configured to discharge the ozone water and the miscible liquid simultaneously or alternately to mix both of the ozone water and the miscible liquid at the discharge-receiving side part.

20. The substrate cleaning device as claimed in claim 19, wherein
the miscible liquid supply unit is configured to discharge the miscible liquid at a temperature of 40° C. or higher.

21. The substrate cleaning device as claimed in claim 19, further comprising
a shower head having a plurality of ozone water outlets that discharge the ozone water of the ozone water supply unit, and a plurality of miscible liquid outlets that discharge the miscible liquid of the miscible liquid supply unit.

22. The substrate cleaning device as claimed in claim 19, further comprising
a pair of shower heads each having a plurality of ozone water outlets that discharge the ozone water of the ozone water supply unit, and a plurality of miscible liquid outlets that discharge the miscible liquid of the miscible liquid supply unit,
wherein the pair of shower heads are arranged so as to face each other with respect to the substrate.

23. The substrate cleaning device as claimed in claim 19, wherein
the support portion rotatably supports the substrate.

24. The substrate cleaning device as claimed in claim 19, wherein
a resist layer is formed on the discharge-receiving side part of the substrate.

25. The substrate cleaning device as claimed in claim 24, wherein
a hardened layer is formed on a surface of the resist layer.

26. A substrate cleaning method comprising:
an ozone water generation step of receiving, in a gas-liquid mixer, ozone gas and a solvent that can dissolve the ozone gas, and generating ozone water;
an ozone water supply step of discharging the ozone water to a substrate that is supported by a support portion; and
a miscible liquid supply step of discharging a miscible liquid that is miscible with the ozone water, to the substrate,
wherein the gas-liquid mixer includes:
a solvent flow passage through which the solvent flows; and
an ozone gas introduction passage which is connected to the solvent flow passage and which introduces the ozone gas into the solvent flow passage, and
the gas-liquid mixer receives the ozone gas at an ozone concentration of 50 vol % or more and at an ozone partial pressure of 30 kPa (abs) or less,
wherein in the miscible liquid supply step, in a state in which the substrate is located in a direction of discharge of the ozone water by the ozone water supply step, the miscible liquid is discharged to a discharge-receiving side part, which is a side where the ozone water is discharged, of the substrate at a temperature that is higher than that of the ozone water discharged by the ozone water supply step, and
wherein the ozone water supply step and the miscible liquid supply step are performed simultaneously or alternately, and both of the ozone water and the miscible liquid are mixed at the discharge-receiving side part.

27. The substrate cleaning method as claimed in claim 26, wherein
in the miscible liquid supply step, the miscible liquid is discharged at a temperature of 40° C. or higher.

28. The substrate cleaning method as claimed in claim 26, wherein
the ozone water supply step and the miscible liquid supply step are performed using a shower head having a plurality of ozone water outlets that discharge the ozone water, and a plurality of miscible liquid outlets that discharge the miscible liquid.

29. The substrate cleaning method as claimed in claim 26, wherein
the ozone water supply step and the miscible liquid supply step are performed using a pair of shower heads each having a plurality of ozone water outlets that discharge the ozone water, and a plurality of miscible liquid outlets that discharge the miscible liquid, and
the pair of shower heads are arranged so as to face each other with respect to the substrate.

30. The substrate cleaning method as claimed in claim 26, wherein
the support portion rotatably supports the substrate.

31. The substrate cleaning method as claimed in claim 30, wherein
when both of the ozone water supply step and the miscible liquid supply step are performed alternately, a cycle of the ozone water supply step, the miscible liquid supply step and a rotation step that is performed in a state in which both of the ozone water supply step and the miscible liquid supply step are stopped, is performed a plurality of times.

32. The substrate cleaning method as claimed in claim 26, wherein
a resist layer is formed on the discharge-receiving side part of the substrate.

33. The substrate cleaning method as claimed in claim 32, wherein
a hardened layer is formed on a surface of the resist layer.

34. A semiconductor device manufacturing method comprising a step of manufacturing a semiconductor device by using a substrate cleaned by the substrate cleaning method as claimed in claim 26.

35. The semiconductor device manufacturing method as claimed in claim 34, wherein
a resist layer is formed on a discharge-receiving side part of the substrate.

36. The semiconductor device manufacturing method as claimed in claim 35, wherein
a hardened layer is formed on a surface of the resist layer.
